(19) United States
(12) Patent Application Publication
(10) Pub. No.: US 2010/0155883 A1
(43) Pub. Date: Jun. 24, 2010

(54) INTEGRATED MEMS AND IC SYSTEMS AND RELATED METHODS

(75) Inventors: Josef-Stefan Wenzler, Dorchester, MA (US); Tyler Dunn, Boston, MA (US); Shyamsunder Erramilli, Quincy, MA (US); Pritiraj Mohanty, Los Angeles, CA (US)

Correspondence Address: WOLF GREENFIELD & SACKS, P.C., 600 ATLANTIC AVENUE, BOSTON, MA, 02210-2206, US

(73) Assignee: Trustees of Boston University, Boston, MA (US)

(21) Appl. No.: 12/609,354

(22) Filed: Oct. 30, 2009

Related U.S. Application Data
(60) Provisional application No. 61/110,026, filed on Oct. 31, 2008.

(51) Int. Cl. H01L 27/02; H02N 11/00; G01H 11/06; H01L 41/107

(52) U.S. Cl. 257/528; 310/300; 310/323.21; 310/318; 257/E27.009

(57) ABSTRACT

An integrated MEMS and IC system (MEMSIC), as well as related methods, are described herein. According to some embodiments, a mechanical resonating structure is coupled to an electrical circuit (e.g., field-effect transistor). For example, the mechanical resonating structure may be coupled to a gate of a transistor. In some cases, the mechanical resonating structure and electrical circuit may be fabricated on the same substrate (e.g., Silicon (Si) and/or Silicon-on-Insulator (SOW and may be proximate to one another.

### RELATED APPLICATIONS

This application claims priority to U.S. Provisional Application No. 61/110,026, filed Oct. 31, 2008, which is incorporated herein by reference in its entirety.

### FIELD OF INVENTION

The invention relates generally to integrated micro-electro-mechanical systems (MEMS) and integrated chip (IC) systems, and more particularly, to integrating a nanomechanical resonator with a transistor, as well as related methods.

### BACKGROUND OF INVENTION

Integration of mechanical and electrical systems on a single chip remains a serious challenge to IC designers and researchers. In particular, the integration of MEMS or nano-electro-mechanical systems (NEMS) with other electronic systems is of great interest to researchers due to the increasing use of mechanical systems with electronic systems. The integration of mechanical systems operating at higher frequencies (i.e., MHz or higher) with electronic systems has been particularly difficult and has posed several problems due to high parasitic losses.

### SUMMARY OF INVENTION

Integrated MEMS and IC system (MEMSIC), as well as related methods, are described herein.

According to one aspect, an integrated circuit is provided. The integrated circuit comprises an electrical circuit and a mechanical resonating structure that has a resonating element including at least one dimension less than 100 microns. The mechanical resonating structure is coupled to the electrical circuit. The mechanical resonating structure and the electrical circuit are integrated on a first substrate.

According to another aspect, an integrated circuit is provided. The integrated circuit comprises an electrical circuit and a mechanical resonating structure that has a resonating element. The mechanical resonating structure is designed to provide an output signal at a frequency of greater than 1 MHz. The mechanical resonating structure is coupled to the electrical circuit. The mechanical resonating structure and the electrical circuit are integrated on a first substrate.

According to another aspect, a device is provided. The device comprises a mechanical resonating structure. The device further comprises a first electric circuit comprising at least one transistor. At least one gate of the at least one transistor is coupled to the mechanical resonating structure. The mechanical resonating structure and the first electric circuit are integrated on a first substrate.

According to another aspect, a device comprises a substrate, a mechanical resonating structure integrated on the substrate, and a transistor integrated on the substrate and having a control terminal coupled to the mechanical resonating structure. In some embodiments, the control terminal of the transistor is directly coupled to the mechanical resonating structure and in some embodiments is configured to be controlled by vibration of the mechanical resonating structure. In some embodiments the control terminal is electrostatically coupled to the mechanical resonating structure, and in some such embodiments is configured to be controlled by vibration of the mechanical resonating structure. In some embodiments, the transistor is a field effect transistor and the control terminal is a gate terminal.

This Summary is not exhaustive of the scope of the present inventions. Moreover, this Summary is not intended to be limiting of the inventions and should not be interpreted in that manner. While certain embodiments have been described and/or outlined in this Summary, it should be understood that the present inventions are not limited to such embodiments, description and/or outline, nor are the claims limited in such a manner. Indeed, many others embodiments, which may be different from and/or similar to, the embodiments presented in this Summary, will be apparent from the description, illustrations and claims, which follow. In addition, although various features, attributes and advantages have been described in this Summary and/or are apparent in light thereof, it should be understood that such features, attributes and advantages are not required whether in one, some or all of the embodiments of the present inventions and, indeed, need not be present in any of the embodiments of the present inventions.

Other aspects, embodiments and features of the invention will become apparent from the following detailed description of the invention when considered in conjunction with the accompanying drawings. All patent applications and patents incorporated herein by reference are incorporated by reference in their entirety. In case of conflict, the present specification, including definitions, will control.

### BRIEF DESCRIPTION OF THE DRAWINGS

FIG. 1 shows a block diagram of an IC with mechanical structures and electrical circuitry according to embodiments of the present invention.

FIG. 2A shows a block diagram of an IC with a mechanical resonating structure, a first electric circuit, and a calibration circuit according to embodiments of the present invention.

FIG. 2B shows a diagram of an IC having a resonating element according to embodiments of the present invention.

FIG. 3 shows a block diagram of an IC with a actuation, detection, and resonating elements, and a transistor according to embodiments of the present invention.

FIG. 4 shows a device with a MEMSIC and additional circuitry according to embodiments of the present invention.

FIG. 5A shows a diagram of an electrostatic and a FET detection setup for the MEMSIC as described in Example 1.

FIG. 5B shows a schematic of the MEMSIC as described in Example 1.

FIG. 5C shows a cross-section of the MEMSIC as described in Example 1.

FIG. 6 shows a current-voltage diagram and transconductance as a function of voltage for a MEMSIC device as described in Example 1.

FIG. 7A shows a frequency response of a MEMSIC device measured via an electrostatic method as described in Example 1.

FIG. 7B shows a relationship between resonance and voltage and a relationship between frequency and voltage as described in Example 1.

FIG. 8 shows the measured resonance frequencies of a MEMSIC device using the electrostatic and FET methods as described in Example 1.

In the drawings, the same reference numbers identify identical or substantially similar elements or acts. The drawings illustrate particular embodiments for the purpose of describing the claimed invention, and are not intended to be exclusive or limiting in any way. The figures are schematic and are not intended to be drawn to scale. For purposes of clarity, not every component is labeled in every figure. Nor is every component of each embodiment of the invention shown where illustration is not necessary to allow those of ordinary skill in the art to understand the invention.

In the course of the detailed description to follow, reference will be made to the attached drawings. These drawings show different aspects of the present inventions and, where appropriate, reference numerals illustrating like structures, components, materials and/or elements in different figures are labeled similarly. It is understood that various combinations of the structures, components, materials and/or elements, other than those specifically shown, are contemplated and are within the scope of the present inventions.

### DETAILED DESCRIPTION

An integrated MEMS and IC system (MEMSIC), as well as related methods, are described herein. According to some embodiments, a mechanical resonating structure is coupled to an electrical circuit or an electrical circuit component (e.g., field-effect transistor). For example, the mechanical resonating structure may be coupled to a control terminal (e.g., a gate) of a transistor. In some such cases, the coupling may be a direct coupling, and in some cases the coupling may be an electrostatic coupling. In some cases, the mechanical resonating structure and electrical circuit may be fabricated on the same substrate (e.g., Silicon (Si) and/or Silicon-on-Insulator (SOD) and may be proximate to one another. By situating the electrical circuit in proximity of the mechanical resonating structure, the MEMSIC can operate with lower parasitic losses, utilize less chip area, and be fabricated at a lower cost. In some cases, the mechanical resonating structure has a dimension less than 100 microns and can output a signal at high frequencies (e.g., greater than 1 MHz or 1 GHz).

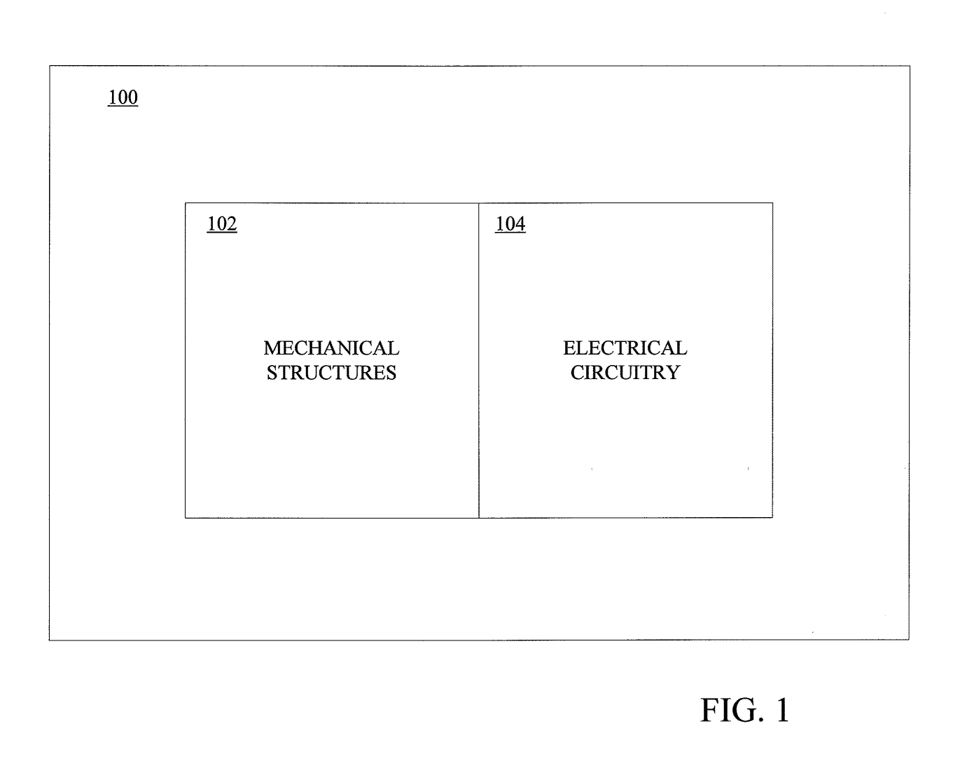

FIG. 1 shows a block diagram of an integrated circuit (IC) 100. In general, the IC may comprise any electrical and/or mechanical hardware and may be large scale, medium scale or small scale. An IC may include, for example, semiconductor devices, packaged ICs, active devices or passive devices. As illustrated in FIG. 1, an IC according to one embodiment comprises electrical circuitry 104 and mechanical structures 102. Electrical circuitry can include circuits such as phase-locked loops, charge pumps, sensors, filters, amplifiers, transistors and any active device. Mechanical structures can include, for example, resonators. The mechanical structures may be independent of or coupled to one or more elements in the electrical circuitry. For example, in some cases, the mechanical structures may perform a function while the electrical circuitry may perform another function independent of the mechanical structure's function. In other cases, the functionality of the mechanical structures and the electrical circuitry may depend on one another. In general, connectivity between the mechanical structures and the electrical circuitry may vary and depend on the particular IC application.

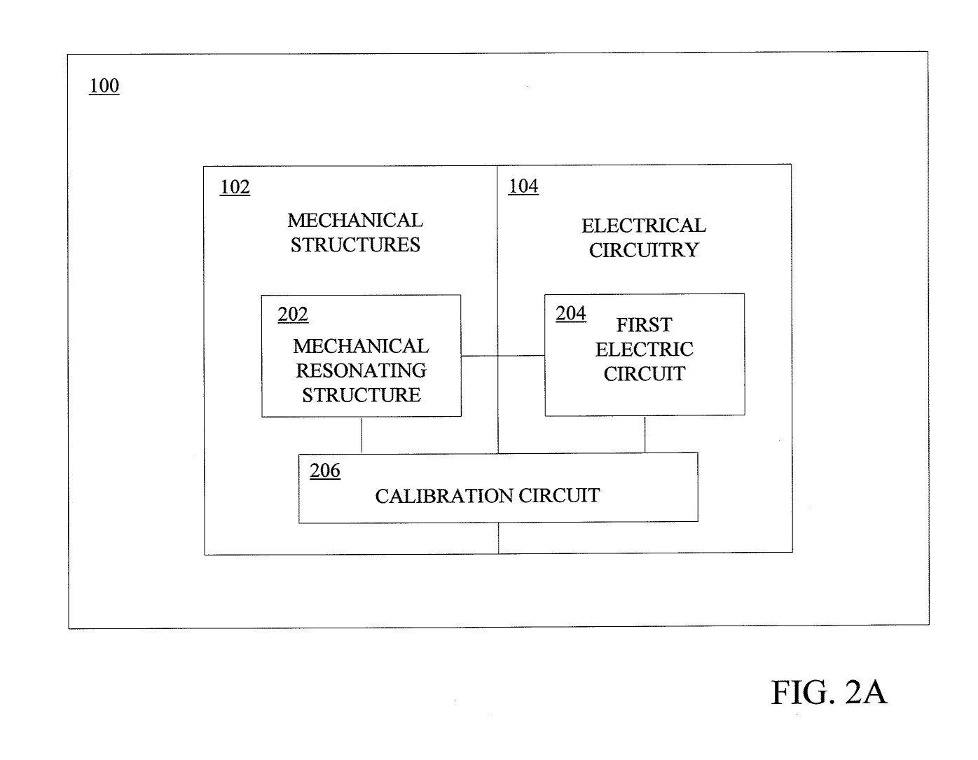

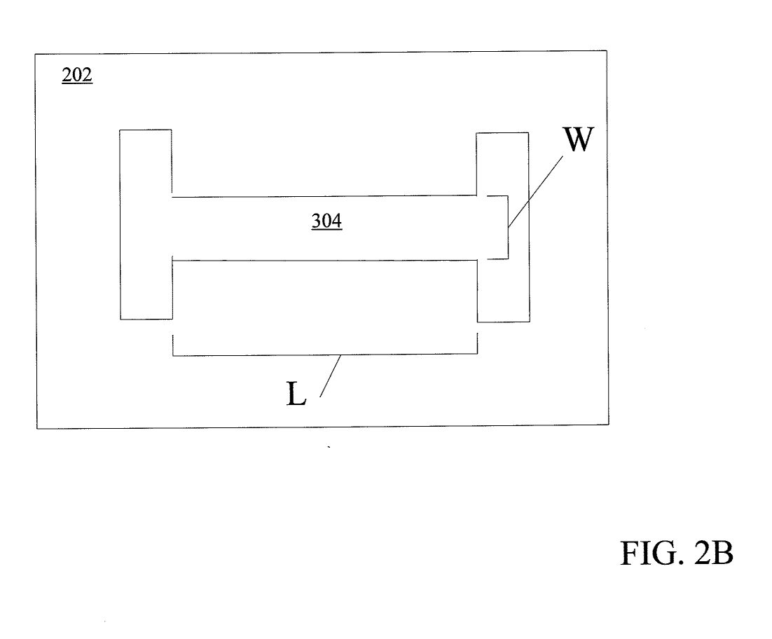

According to some embodiments, a mechanical resonating structure can be coupled to a electrical circuit. That is, the mechanical resonating structure and electrical circuit can send signals to and receive signals from one another. In FIG. 2A, for example, the mechanical resonating structure 202 can produce a signal used as an input in the first electric circuit 204. Similarly, the first electric circuit may generate an output used to drive the mechanical resonating structure. A calibration circuit 206 can be connected to the mechanical resonating structure and the first electric circuit. The calibration circuit can be mechanical, electrical or both. Suitable designs for the mechanical resonating structure, the first electric circuit and the calibration circuit are described in further detail below.

In some embodiments, a signal generated by the mechanical resonating structure may be converted to an electrical signal and provided to the first electric circuit, using capacitive coupling, piezoelectric techniques, magnetoelectric techniques, magnetomotive techniques or any other suitable technique(s). Similarly, an electrical signal may be converted and provided to the mechanical resonating structure using any suitable technique. In general, the mechanical resonating structure may be coupled to the first electric circuit in any suitable manner. In some cases, the first electric circuit can generate an output based on the mechanical resonating structure's signal. In some embodiments, the first electric circuit can receive a signal from the mechanical resonating structure and can further process or manipulate the resonating structure's signal.

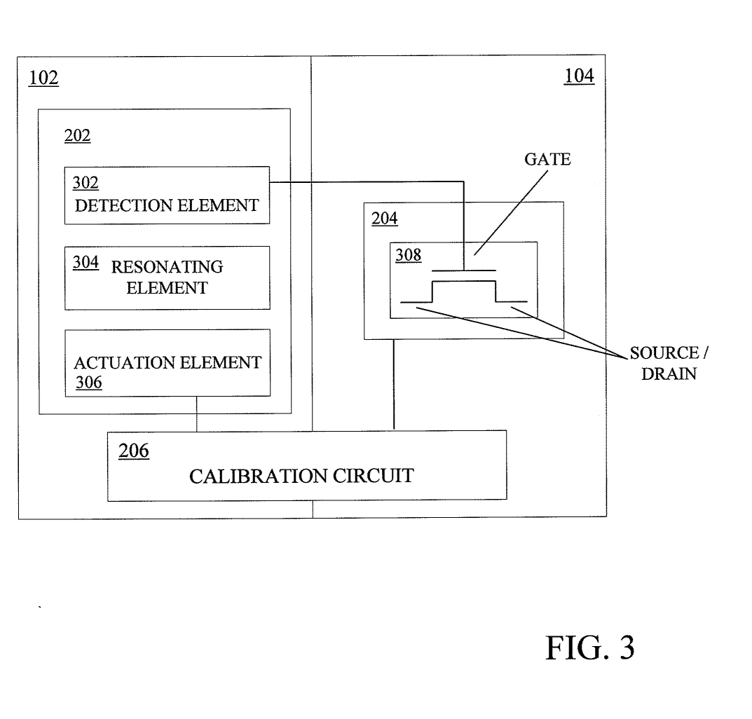

The mechanical resonating structure may be a passive device that produces a signal with desired characteristics using mechanical elements as shall be described further in FIGS. 2B and 3. The mechanical resonating structure can be tuned to adjust an amplitude or frequency of the signal. The tuning can be accomplished by, for example, modifying the mechanical resonating structure's design parameters such as geometry, dimensions and material type. A mechanical resonating structure can produce self-sustained oscillations by being connected to a drive circuit with active electronic circuits. In some cases, the signal generated by the mechanical resonating structure may have a frequency, for example, in the upper MHz range (e.g., 10 MHz to 100 MHz) or the GHz range (e.g., 100 MHz to 20 GHz) or a KHz to GHz (broadband) range (e.g., 10 KHz to 20 GHz). In some cases, the generated signal may have a frequency of at least 10 KHz (e.g., 10 KHz to 1 MHz) or at least 1 GHz (e.g., between 1 GHz and 10 GHz). In some cases, the generated signal may have a frequency of at least 1 MHz (e.g., 1 MHz to 20 GHz).

In general, a variety of different mechanical resonating structure designs may be used. It should be understood that any suitable designs of the mechanical resonating structure may be used including, in some embodiments, designs with different arrangements of major and minor elements. In some embodiments, at least one of the dimensions is less than 1 micron; in some embodiments, at least one of the dimensions is less than 50 microns; in some embodiments, at least one of the dimensions is less than 100 microns; and in some embodiments, the major element (i.e., the largest of the dimensions) may have a width and/or thickness of less than 100 microns (e.g., between 10 nm and 100 microns). It should be understood that dimensions outside the above-noted ranges may also be suitable. Suitable mechanical resonating structures have been described, for example, in International Publication No. WO 2006/083482 and in U.S. patent application Ser. No. 12/028,327, filed Feb. 8, 2008, which are both incorporated herein by reference in their entireties.

The first electric circuit may be any electrical element with an input and an output. For example, the first electric circuit may include phase-locked loops, charge pumps, filters, amplifiers and transistors. As discussed further in FIG. 3, the first electric circuit may include one or more transistors configured to operate based on the mechanical resonating structure's output.

A calibration circuit may be connected to both the first electric circuit and the mechanical resonating structure, as shown in FIG. 2A. The calibration circuit may be any suitable circuit capable of receiving signals indicative of biasing parameters for modifying the operation of the mechanical resonating structure. In some cases, the calibration circuit may generate a signal instructing the drive circuit to modify the operation of the mechanical resonating structure. In some cases, the calibration circuit can be used to provide feedback from the first electric circuit to the mechanical resonating structure. In some cases, the calibration circuit can be used to improve or rectify the mechanical resonating structure's output signal. For example, inaccuracies in manufacturing ICs and packages often result in process variations or malfunctioning components which can lead to undesirable outputs. The calibration circuit can provide the means to rectify errors including but not limited to process variations, thermal variations, and jitter. The calibration circuit may include multiple circuits and compartments where each compartment is designed to perform a desired calibration function. In general, the calibration circuit may have a number of different configurations which may be suitable.

Monitoring mechanisms, such as sensors and/or detectors, may be integrated in the calibration circuit to monitor the external and internal conditions (e.g., temperature, heat and humidity) of the IC 100 and/or to monitor signal quality factors (e.g., frequency, phase, noise, amplitude). In general, any suitable monitoring mechanism may be used.

The calibration circuit may include one or more active and/or passive circuit components, either as discrete components, or any other suitable form, as the various aspects of the invention are not limited to any particular implementation of the calibration circuit.

FIG. 2B illustrates an example of a mechanical resonating structure which includes a resonating element 304. It should be appreciated that a mechanical resonating structure can include additional suitable components and structures. In some embodiments, the resonating element can be a micromechanical resonator designed to vibrate at high frequencies. In general, a variety of different resonator designs may be used for the resonating element. For example, the designs may include major and minor elements, beams (e.g., suspended beams), platforms and the like; the designs can include and are not limited to comb-shaped, circular, rectangular, square, or dome-shaped designs. Suitable designs have been described, for example, in International Publication No. WO 2006/083482 and U.S. patent application Ser. No. 12/028,327, filed Feb. 8, 2008, which are incorporated herein by reference in their entireties.

As shown in FIG. 2B, a resonating element can be a beam-like structure having a length (L) and width (W). The dimensions of the length and width are selected, in part, based on the desired performance including the desired frequency range of input and/or output signals associated with the resonating element. In some embodiments, at least one of the length or width is less than 1 micron; in some embodiments, at least one of the length or width is less than 50 microns; and in some embodiments, at least one of the length or width is less than 100 microns. In some embodiments, the beam may have a width and/or thickness of less than 100 microns (e.g., between 10 nm and 100 microns). It should be understood that dimensions outside the above-noted ranges may also be suitable. Suitable dimensions and ranges have been described, for example, in International Publication No. WO 2006/083482 which is incorporated herein by reference above.

FIG. 3 illustrates another example of a mechanical resonating structure 202. According to some embodiments, a mechanical resonating structure can include a detection element 302 and/or an actuation element 306 in addition to a resonating element 304; and the first electric circuit can include at least one transistor 308. It should be understood that other mechanical resonating structures may be suitable.

The actuation element 302 is the driving mechanism of the mechanical resonating structure. That is, the actuation element is used to drive the resonating element by actuating (i.e., moving) the resonating element to vibrate at a desired frequency. In general, any suitable actuation element and associated excitation technique may be used to drive the resonating element. Examples of suitable actuation elements include micromechanical actuation elements having a dimension of less than 100 microns. In some cases, the actuation element uses a capacitive (i.e., electrostatic) excitation technique to actuate the resonating structure. However, it should be understood that other excitation techniques may be used in certain embodiments such as mechanical, electromagnetic, piezoelectric or thermal.

The detection element 206 detects motion of the resonating element. According to some embodiments, the detection element can use a capacitive (i.e., electrostatic) or a field effect transistor (FET) technique to sense the motion of the resonating element. However, it should be understood that other detection techniques may be used in certain embodiments such as mechanical, electromagnetic, piezoelectric or thermal. In general any suitable detection element structure and associated detection technique may be used.

In some embodiments, the detection element comprises a micromechanical structure. In some embodiments, the detection element may have a structure similar to the actuation element. In some embodiments, the detection element and/or actuation element may be fixed or suspended structures. In some embodiments, the detection element and the actuation element can be the same structure. That is, the device may include a single element that functions as both the actuation element and the detection element.

As illustrated in FIG. 3, the detection element 302 of the mechanical resonating structure 202 may be coupled to the first electric circuit 204, which may comprise at least one transistor. In some cases, the detection element and the first electric circuit can be separated by a distance of at least 100 nanometers (nm) or at most 10 microns. In some cases, the distance between the detection element and the first electric circuit may range from 100 nm to 1,000 nm.

In some embodiments, the detection element may be coupled to a transistor in the first electric circuit. In some cases, the detection element may be coupled to a gate of a transistor 308 in the first electric circuit. In such cases, the signal provided by the detection element can control the operability of the transistor. The signal can also be supplied to more than one element in the first electric circuit.

In general, transistor 308 can be any suitable type of transistor. The transistor can be a bipolar junction transistor (e.g., BJT, HBT), a field-effect transistor (e.g., FET, MOSFET, MESFET, IGFET) or an insulated gate bipolar transistor (IGBT). The transistor can be n-channel, p-channel, NPN or PNP, and can be built on any suitable substrate (e.g., silicon (Si), germanium (Ge), SiGe, gallium arsenide (GaAs), Silicon carbide, Silicon dioxide or any type of Silicon-on-insulator (SOI) material). In preferred embodiments, the transistor can be built on Si and/or SOI substrate.

In some embodiments, the transistor is a FET transistor with a source, drain and gate. The transistor can be activated or “turned-on” when a voltage applied at the gate exceeds a threshold voltage of the transistor. The source and drain of the transistor are separated by a channel. The transistor channel has a channel length and a channel width. In some cases, the channel length may have a length ranging from 100 nm to 10 microns. In some cases, the channel length may be less than 500 nm. In some cases, the channel width may have a width ranging from 50 nm to 1 micron.

As a voltage applied to the gate increases beyond the threshold voltage of the transistor, a larger number of electrons may flow in the channel from the source to the drain. This allows charges and/or a current to flow between the source and drain of a transistor. Accordingly, the signal applied to the gate of the transistor can control the operability of the transistor and any other circuits or elements connected to the transistor.

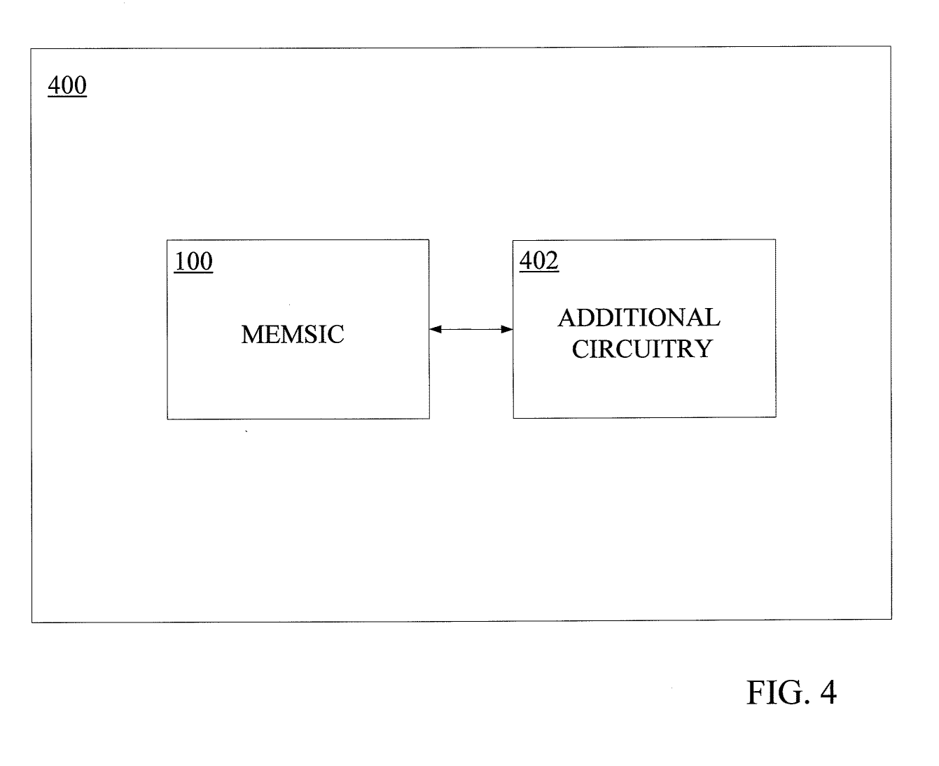

FIG. 4 illustrates an example of a device 400 in which the integrated MEMSIC device 100 is connected to additional circuitry 402. Examples of device 400 include and are not limited to a timing oscillator, mixer, tunable meter, duplexer, gyroscope, accelerometer, microphone and sensor. In general, device 400 can represent any device comprising MEMS and additional electromechanical components. Examples of additional circuitry include and are not limited to compensation circuits, PLLs, filters and charge pumps. The additional circuitry may be implemented on the same chip/substrate or may be connected externally to the MEMSIC. The signal generated by the mechanical resonating structure in the MEMSIC can, at least partially, control the performance of additional circuitry through the first electric circuit.

The following example illustrates an exemplary embodiment and should not be considered limiting. The example is provided for illustrative purposes.

### Example 1

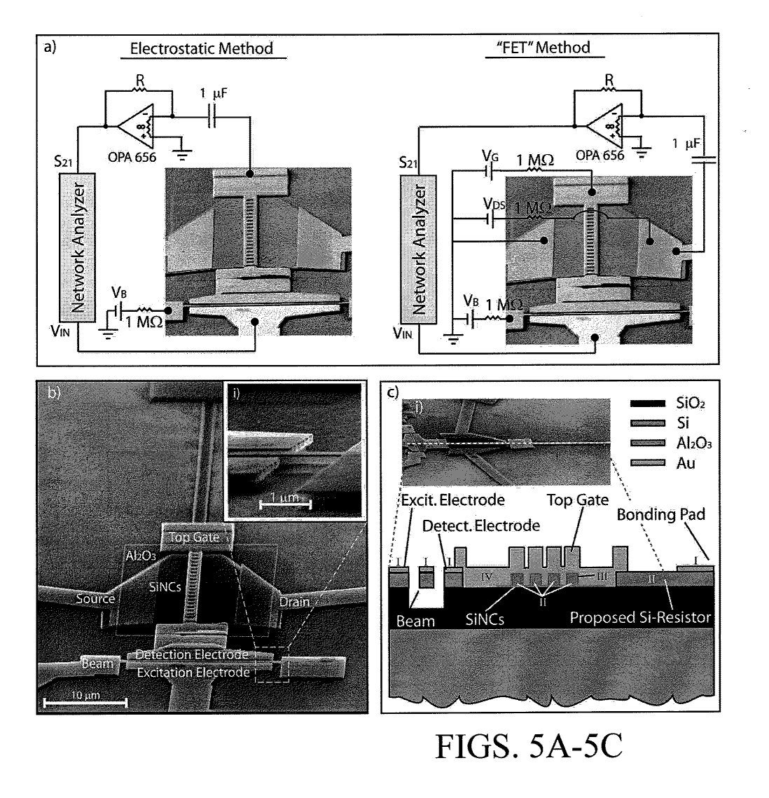

This example describes the properties as well as fabrication and testing process for a MEMSIC device. FIGS. 5A-5C illustrate a MEMSIC device with a doubly clamped mechanical resonating structure (e.g. beam) that may be integrated with a Si Nano-Channel (SiNC) FET to form the IC part of the MEMSIC device, which includes the SiNCs, source, drain and top gate. To actuate the beam, a standard electrostatic method can be utilized whereby a radio-frequency voltage signal, V_{IN}, applied to the nearby excitation element (e.g., excitation electrode) capacitively forces the beam. With the beam held at constant bias, V_{B}, relative to the excitation/detection electrodes, the subsequent motion of the beam can induce charges on the detection gate, which can double as the top gate of the SiNC FET. Assuming a parallel plate capacitance, C_{B}, between the beam and the adjacent electrodes, this current can be approximated as

$${i}_{1} = \frac{d Q}{d t} \approx Δ Q \cdot {f}_{0} \approx {V}_{B} \frac{{C}_{B} {x}_{o}}{d} {f}_{o} ,$$

where xₒ can be the maximum displacement of the beam, d can be the equilibrium separation between the detection/excitation electrodes and the beam, fₒ can be the resonant frequency of the beam and ΔQ can be the charge transferred between the beam and the gate per oscillation.

Current i₁ can be detected using an electrostatic detection method and a FET detection method. As shown in FIG. 5A, the electrostatic method can utilize a transimpedance amplification (e.g., OPA 656) before the measurement of an output signal with a network analyzer. The voltage detected by the network analyzer can be approximated as:

$${V}_{OUT 1} = {i}_{1} R \approx - {V}_{B} {C}_{B} \frac{{x}_{o}}{d} {f}_{o } R \qquad ( 1 )$$

where R is the resistor in the feedback loop of the amplifier.

The FET method (also shown in FIG. 5A) can take advantage of the electric charges transferred between the beam and the detection electrode to modulate the conductance of the FET and thus the drain-source current can pass through the charge sensitive SiNC FET. The resulting change in current,

$${i}_{2} = {g}_{m} \frac{Δ Q}{{C}_{G}} ,$$

can then be detected in exactly the same way as for the standard electrostatic method, leading to a voltage:

$${V}_{OUT 2} = {i}_{2} R \approx {g}_{m} {V}_{B} \frac{{x}_{o}}{d} \frac{{C}_{B}}{{C}_{G}} , \qquad ( 2 )$$

where gₘ is the transconductance of the FET, and C_{G} the capacitance between the top gate and the SiNCs. Comparing the detected voltages for the two methods with typical values for fₒ, gₘ, and C_{G} leads to:

$$\frac{{V}_{OUT 2}}{{V}_{OUT 1}} = \frac{{g}_{m}}{{f}_{o} {C}_{G}} \sim \frac{{10}^{- 6} \frac{1}{Ω}}{{10}^{6} Hz \cdot {10}^{- 13} F} = 10. \qquad ( 3 )$$

Thus, in theory, the FET method measurement setup shown in FIG. 5A can be used as an on-chip amplifier for improved displacement detection of nanomechanical resonators.

MEMSIC devices can be fabricated from silicon-on-insulator (SOI) wafers by e-beam lithography and a series of nanomachining techniques. The fabrication process and a cross section of the device as cut through the middle of the SiNCs are illustrated, for example, in FIG. 5C. The roman numerals represent the order of the fabrication process. As a first step (I), the beam, excitation/detection electrodes, and drain/source electrodes can be patterned and metalized. Typical beam dimensions can be 15-22 μm in length, 200-300 nm in width and 84-150 nm in thickness, along with a gap of 100-300 nm separating the beam and electrodes. The second step (II) of fabrication may be the creation of the SiNCs, which can be carved into the device layer of the SOI wafer using a chromium mask and reactive ion etching (RIE). After removal of the chromium mask, a thin (15-30 nm) layer of insulating Al₂O₃ can be deposited locally via atomic layer deposition (ALD) to electrically isolate the top gate from the SiNCs (step III). Each FET can consist of between 5-20 SiNCs, each 50-500 nm wide, 0.5-6 μm long and 84-150 nm thick. Next, a thick (200 nm) layer of gold can be deposited on top of the SiNCs forming the top gate and connecting the detection electrode with the electrode pad (step IV). Finally, the beam can be suspended via, for example, a hydrofluoric acid (HF) vapor etch, although this part of the process can also be achieved by a dry etch. In total, device fabrication can involve 4 e-beam lithography steps, 4 metal evaporations, 1 RIE etch and 1 vapor HF etch. Several MEMSIC devices can be constructed in a similar manner with varying dimensions and without compromising the quality of the SiNC FETs.

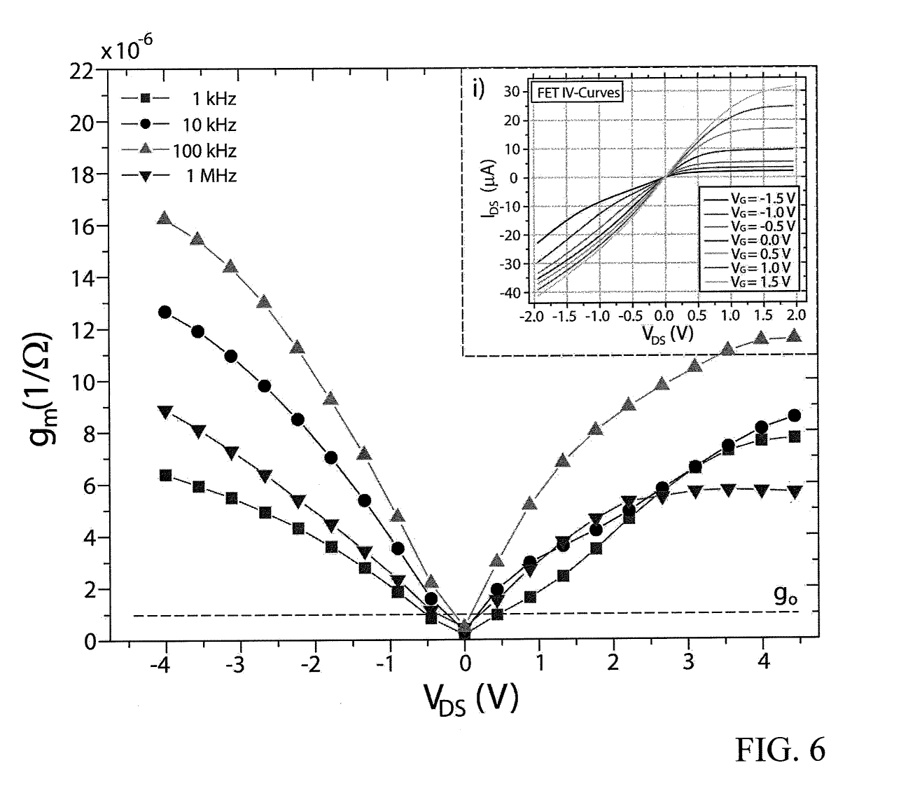

Testing of the beam and FET can be accomplished individually. As elucidated in (3), transconductance gₘ impacts the effectiveness of the SiNC FET operation. FIG. 6 displays typical results for gₘ as a function of drain-source voltage V_{DS} (V_{G}=0.5 V for all data points) for frequencies ranging from 1 kHz to 1 MHz as well as a set of static IV-curves of the FET (inset of FIG. 6). The dotted line in FIG. 6 represents an estimate for gₒ, the transconductance leading to unity gain (V_{OUT1}=V_{OUT2}) at 10 MHz. By adjusting V_{DS}, we can achieve gₘ≈8 gₒ, gₘ≈13 gₒ, gₘ≈16 gₒ and gₘ=9 gₒ for 1 kHz, 10 kHz, 100 kHz and 1 MHz, respectively. Increase in transconductance from 1 to 100 kHz can be a consequence of the measurement circuit, specifically the change in impedance of a capacitor at the input of the transimpedance amplifier, necessary when using DC biasing. By contrast, the drop in gₘ at 1 MHz can relate to the FET operation itself, signaling approach of the intrinsic cut-off frequency, f_{T}, of the SiNC FET. This cut-off frequency can be reached when the FET gain drops to unity:

$${f}_{T} = \frac{{g}_{m}}{2 π ( {C}_{G} + {C}_{GD} + {C}_{GS} )} \approx \frac{{g}_{m}}{2 π {C}_{G }} \approx \frac{{10}^{- 6} \frac{1}{Ω}}{2 π \cdot {10}^{- 13} F} \approx {10}^{6} Hz , \qquad ( 4 )$$

where C_{GD} and C_{GS} can be the parasitic capacitances between the gate, and drain and source, respectively, and C_{GD} , C_{GS}<<C_{G}. This frequency, which can be intimately related to the gain, also defines the bandwidth of the device, and can easily be improved by orders of magnitude (>1 GHz) by varying the doping of the device layer or the dimensions of the SiNCs.

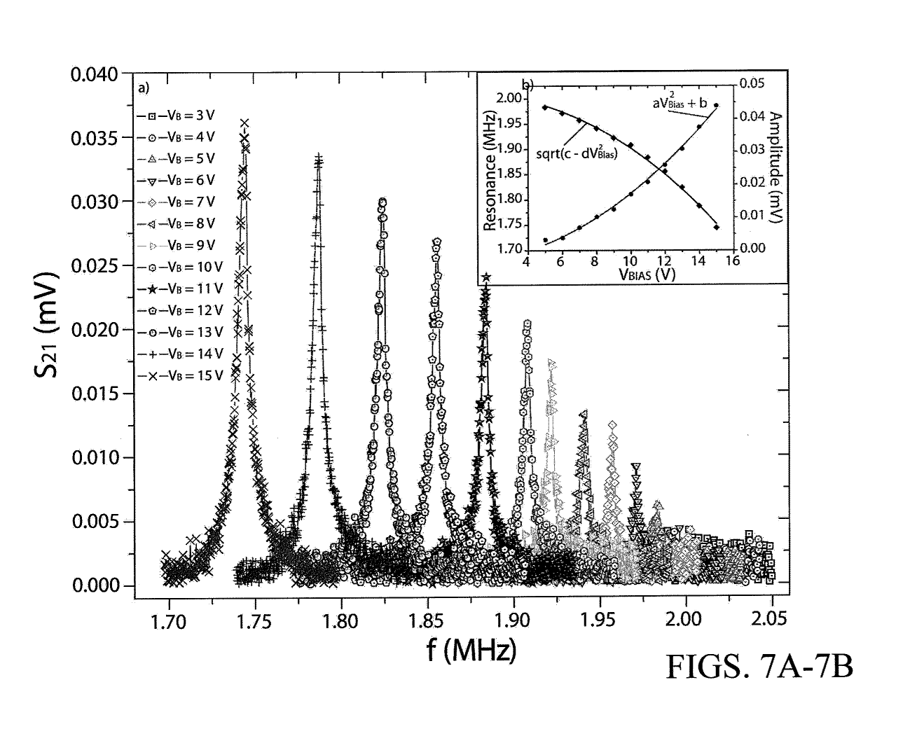

The nanomechanical beam can also be tested using the electrostatic method described previously, by focusing on the dependence of the resonance amplitude and frequency on bias voltage V_{B}. Typical resonances can exhibit measured amplitudes of ˜100 μV and frequencies ranging from 1-5 MHz. Resonances for several different bias voltages are shown in FIG. 7A. The corresponding bias voltage dependencies with fits are depicted in FIG. 7B, and agree well with theory.

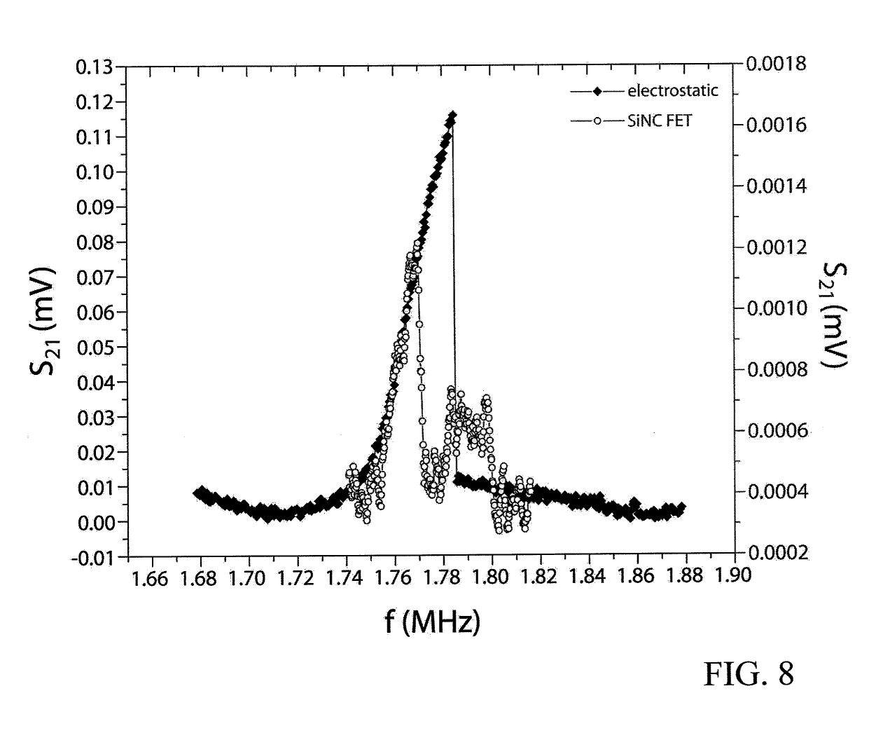

Having demonstrated that both the beam and the SiNC FET properly function independently, the beam resonance can be measured via the FET method described previously. The result of this measurement is depicted in FIG. 8 (blue, circles), with the data obtained measuring the resonance electrostatically (red, squares) included for comparison. As can be appreciated from FIG. 8, the resonance measured using the FET method is about two orders of magnitude smaller than the resonance using the standard electrostatic detection. The reasons for the reduction in signal size are twofold. First, capacitance in the detection line can be dominated by parasitic contributions due to the cables and the sample stage. Parasitic capacitances, C_{PAR} and C_{G}, can be estimated to be C_{PAR}≈10⁻¹² F and C_{G}=10⁻¹³ F, leading to the reduction in the charge accumulation at the SiNCs by a factor of ten. Second, the RC-circuit formed by the 1 MΩ resistor in the gate line and C_{PAR} has a time constant of τ=RC_{PAR}≈10⁻⁶ s. Therefore, voltage build-up at the top gate is exponentially reduced for resonance frequencies

$${f}_{o} \leq \frac{1}{τ} ,$$

Both problems can be solved by micro-machining a high impedance (10⁸-10⁹Ω) silicon on-chip resistor along with the SiNCs, in between the top gate and the bonding pad, thereby reducing the parasitic capacitance to 10⁻¹⁵ F, and improving the time constant τ=R_{Si}C_{G}10⁻⁴ s.

This exemplary example demonstrated the fabrication process and properties of a MEMSIC device. The motion of the mechanical resonating structure can be measured by a room temperature displacement detection technique via the integrated silicon nanochannel field effect transistor. This approach is similar to the conventional MEMS-first concept. The MEMSIC device can be used as an on-chip amplifier for improved motion detection in nanomechanical structures, though for highly sensitive applications such as the quantum measurements larger amplification through the transistor may be required. Under optimal conditions (higher electron mobility, shorter and wider SiNC and higher device layer doping) a device with transconductance

$${g}_{m} = {10}^{- 4} \frac{1}{Ω}$$

and C_{G}=10⁻¹³ F may be possible, which at 1 MHz may result in an estimated gain of three orders of magnitude in voltage in comparison to the standard electrostatic method.

It is understood that the various embodiments shown in the Figures are illustrative representations, and are not necessarily drawn to scale. Reference throughout the specification to “one embodiment” or “an embodiment” or “some embodiments” means that a particular feature, structure, material, or characteristic described in connection with the embodiment(s) is included in at least one embodiment of the present invention, but not necessarily in all embodiments. Consequently, appearances of the phrases “in one embodiment,” “in an embodiment,” or “in some embodiments” in various places throughout the Specification are not necessarily referring to the same embodiment. Furthermore, the particular features, structures, materials, or characteristics can be combined in any suitable manner in one or more embodiments.

Aspects of the methods and systems described herein may be implemented in a variety of component types, e.g., metal-oxide semiconductor field-effect transistor (“MOSFET”) technologies like complementary metal-oxide semiconductor (“CMOS”), bipolar technologies like emitter-coupled logic (“ECL”), polymer technologies (e.g., silicon-conjugated polymer and metal-conjugated polymer-metal structures), mixed analog and digital, etc.

Unless the context clearly requires otherwise, throughout the disclosure, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list; all of the items in the list; and any combination of the items in the list.

Having thus described several embodiments of this invention, it is to be appreciated that various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. An integrated circuit, comprising:
an electrical circuit; and
a mechanical resonating structure having a resonating element including at least one dimension less than 100 microns,
wherein the mechanical resonating structure is coupled to the electrical circuit and the mechanical resonating structure and the electrical circuit are integrated on a first substrate.

2. The integrated circuit of claim 1, wherein the electrical circuit comprises an active device.

3. The integrated circuit of claim 1, wherein the electrical circuit comprises at least one transistor.

4. The integrated circuit of claim 1, wherein the mechanical resonating structure further comprises an actuation element.

5. The integrated circuit of claim 1, wherein the mechanical resonating structure further comprises a detection element.

6. The integrated circuit of claim 3, wherein at least one gate of the at least one transistor is coupled to a detection element of the mechanical resonating structure.

7. The integrated circuit of claim 1, further comprising a calibration circuit coupled to the mechanical resonating structure and to the electrical circuit, the calibration circuit configured to calibrate the mechanical resonating structure.

8. The integrated circuit of claim 1, further comprising a feedback element to provide feedback from the electrical circuit to the mechanical resonating structure.

9. The integrated circuit of claim 1, wherein the first substrate comprises a silicon and/or a silicon-on-insulator substrate.

10. The integrated circuit of claim 1, wherein the first substrate is selected from the group consisting of silicon, silicon-on-insulator, gallium arsenide and silicon germanium.

11. The integrated circuit of claim 1, wherein the mechanical resonating structure is configured to provide an output signal at a frequency of greater than 1 MHz.

12. The integrated circuit of claim 1, wherein the mechanical resonating structure is configured to provide an output signal at a frequency ranging from 100 MHz to 20 GHz.

13. The integrated circuit of claim 1, wherein the mechanical resonating structure is configured to provide an output signal at a frequency ranging from 10 KHz to 1 MHz.

14. The integrated circuit of claim 1, wherein a distance between the electrical circuit and the mechanical resonating structure is between 100 nm and 1,000 nm.

15. The integrated circuit of claim 1, wherein a distance between the electrical circuit and the mechanical resonating structure is at least 100 nm.

16. The integrated circuit of claim 3, wherein a channel situated between a source and a drain of the at least one transistor has a length less than 500 nm.

17. An integrated circuit, comprising:
an electrical circuit; and
a mechanical resonating structure having a resonating element, the mechanical resonating structure designed to provide an output signal at a frequency of greater than 1 MHz,
wherein the mechanical resonating structure is coupled to the electrical circuit and the mechanical resonating structure and the electrical circuit are integrated on a first substrate.

18-25. (canceled)

26. A device, comprising:
a mechanical resonating structure;
a first electric circuit comprising at least one transistor, at least one gate of the at least one transistor being coupled to the mechanical resonating structure; and
wherein the mechanical resonating structure and the first electric circuit are integrated on a first, substrate.

27. The device of claim 26, further comprising a calibration circuit coupled to the mechanical resonating structure and the first electric circuit, the calibration circuit configured to calibrate the mechanical resonating structure.

28-39. (canceled)
